(19) United States
(12) Patent Application Publication
(10) Pub. No.: US 2015/0236476 A1
(43) Pub. Date: Aug. 20, 2015

(54) PULSE MODULATING LASER DRIVER

(71) Applicant: IEE INTERNATIONAL ELECTRONICS & ENGINEERING S.A., Echternach (LU)

(72) Inventors: Laurent Lamesch, Reichlange (LU); Laurent Thiry, Ethe (BE); Norbert Herschbach, Medernach (LU)

(21) Appl. No.: 14/421,476

(22) PCT Filed: Aug. 7, 2013
(86) PCT No.: PCT/EP2013/066564

§ 371 Date: Feb. 13, 2015

(30) Foreign Application Priority Data
Aug. 13, 2012 (LU) 92 061

(51) Int. Cl. H01S 5/042; H01S 5/068

(52) U.S. Cl. CPC H01S 5/0427; H01S 5/06808

(57) ABSTRACT

A pulse modulated illumination source including a light emitting device, and a power source with first and second output terminals for generating DC current, where the illumination source further includes a first controllable switching device and a first signal generator for generating a first electrical control signal for the first controllable switching device, the first controllable switching device being connected in parallel to the light emitting device, where the illumination source further includes a second controllable switching device and a second signal generator for generating a second electrical control signal for the second controllable switching device, the second controllable switching device being connected in series with the at least one light emitting device and the second control signal being out of phase with the first control signal such that the second controllable switching device opens and decouples the light emitting device from the power source when the first controllable switching device closes.

### TECHNICAL FIELD

The present invention generally relates to the area of Time of flight (TOF) 3D distance measurement systems and more particularly to a laser driver to be used in 3D TOF distance measurement systems.

The time-of-flight measurement principle is well known in the field of 3D imaging. 3D cameras (or range cameras) are known that acquire range images in real time based on the time-of-flight (TOF) principle. Such camera generally comprises a light source emitting modulated light into the scene to be imaged in 3D and a sensor pixel array on which the scene is imaged by an optical system. Sensor pixels will hereinafter be referred to as “pixels” for conciseness. The camera then correlates the light detected in the pixels with the light emitted and determines, for each pixel, the phase difference between emitted and received light. This phase difference is proportional to the radial distance between the camera and the part of the scene that is imaged onto the pixel concerned.

### BACKGROUND ART

A camera based time of flight system requires a pulse modulated illumination source. In order to optimize the overall power efficiency, the illumination source should preferably emit a square wave amplitude modulated light output, ideally with a modulation index of 100% and ideally with infinitely small rise and fall times. Typically, one or several lasers or LEDs are used as light emitting devices in the illumination source. Prior art drivers for the light emitting devices have a small rising time but a substantially large falling time, or vice-versa, at high drive currents.

The substantial fall or rise time in conventional laser drivers results from the fact that the circuit path between driver and light emitting devices comprises a certain series wiring inductance, due to the finitely small physical surface spanned by the electrical conductors between driver output and light emitting device. When the driver tries to turn off the current in the light emitting device, said current does not stop immediately due to the series wiring inductance which tries to maintain the current at the same level.

### BRIEF SUMMARY

An improved pulse modulating laser driver is provided herein.

The basic idea underlying the present invention is to add a switch in series to the light emitting devices which is turned off whenever the driver tries to stop the current through the light emitting device. The resulting voltage spike is suppressed by adding an additional voltage limiting circuit.

A pulse modulated illumination source therefore preferably comprises at least one light emitting device, e.g. a laser diode or a laser diode array, and a power source for generating a DC current to be supplied through said at least one light emitting device. The power source comprises a first and a second output terminal and said at least one light emitting device is connected between said first and second output terminals of said power source. The illumination source further comprises a first controllable switching device and a first signal generator for generating a first electrical control signal for said first controllable switching device, said first controllable switching device being connected in parallel to said at least one light emitting device between said first and second output terminals of said power source. According to the invention, the pulse modulated illumination source further comprises a second controllable switching device and a second signal generator for generating a second electrical control signal for said second controllable switching device, said second controllable switching device being connected in series with said at least one light emitting device between said first and second output terminals of said power source, the connection being such that the series connection formed by said second controllable switching device and said at least one light emitting device is connected in parallel to said first controllable switching device between said first and second output terminals of said power source, and said second control signal being out of phase with said first control signal such that said second controllable switching device opens and decouples or disconnects said light emitting device from said power source when said first controllable switching device closes.

In a preferred embodiment of the invention, the pulse modulated illumination source further comprises a voltage limiting circuit, said voltage limiting circuit being connected so as to limit a peak voltage across said second controllable switching device when said second controllable switching device opens. The voltage limiting circuit can for instance be chosen among the many known circuits employed for switched mode power circuits, for example an RC or RCD snubber, or a Z diode, or a diode biased to the required limiting voltage level.

The first and/or second control signals is/are preferably square waves. Furthermore the first control signal and the second control signal have advantageously the same frequency and a phase difference between said first control signal and said second control signal is substantially 180°.

The power source may e.g. comprise a DC current source. Alternatively the power source may comprise a DC voltage source and an inductance coupled in series between the terminals of said power source.

### BRIEF DESCRIPTION OF THE DRAWINGS

Further details and advantages of the present invention will be apparent from the following detailed description of several not limiting embodiments with reference to the attached drawings, in which

FIG. 1 shows a prior art circuit of a prior art laser driver;

FIG. 2 shows the waveform of the current through the light emitting device for the circuit according to FIG. 1;

FIG. 3 shows a circuit of an embodiment of a pulse modulated illumination source according to the present invention; and

FIG. 4 shows the waveform of the current through the light emitting device for the circuit according to FIG. 3.

### DESCRIPTION OF PREFERRED EMBODIMENTS

FIG. 1 shows a circuit as known from the prior art. DC Voltage source 1 supplies a constant voltage to the driver circuit. The voltage is set to such a value that the required peak current flows through the light emitting device when it is modulated. Inductor 2 maintains a substantially constant current through the paralleled switch 3 and light emitting device 4. The advantage of the use of a DC source in series with an inductance compared to a constant DC current source is that the electrical power efficiency is substantially doubled.

Switch 3 is driven by square wave source 5. Square wave source 5 generates a periodic square wave with a duty cycle substantially equal to 50%. Switch 3 is preferably fully switched on or off by square wave source 5. When switch 3 is open, the current maintained by inductor 2 flows through light emitting device 4.

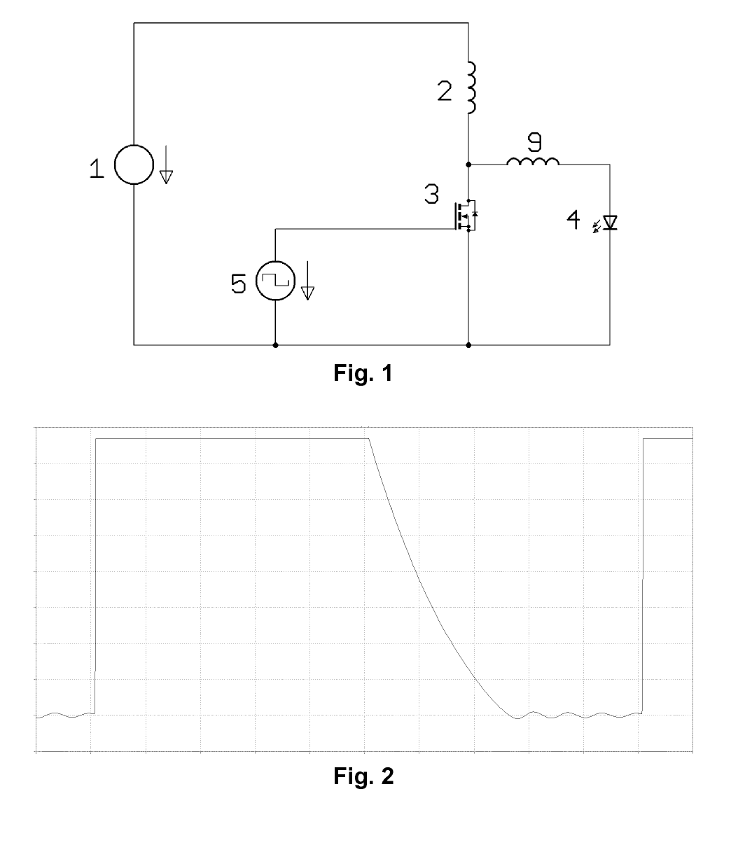

When switch 3 is turned on or closed, switch 3 tries to divert the same current away from the light emitting source 4 towards switch 3. Series wiring inductance 9 however prevents the current through light emitting device 4 from dropping instantly to zero. Series wiring inductance 9 tries to maintain the previous current through the loop formed by series wiring inductance 9, switch 3 and light emitting device 4. As the series wiring inductance cannot be reduced to zero, the fall time of the current through light emitting device consequently cannot be made arbitrarily small. FIG. 2 shows the waveform of the current through light emitting device 4 for an example circuit according to FIG. 1. The X scale is 5 ns per division, Y scale is 2 A per division.

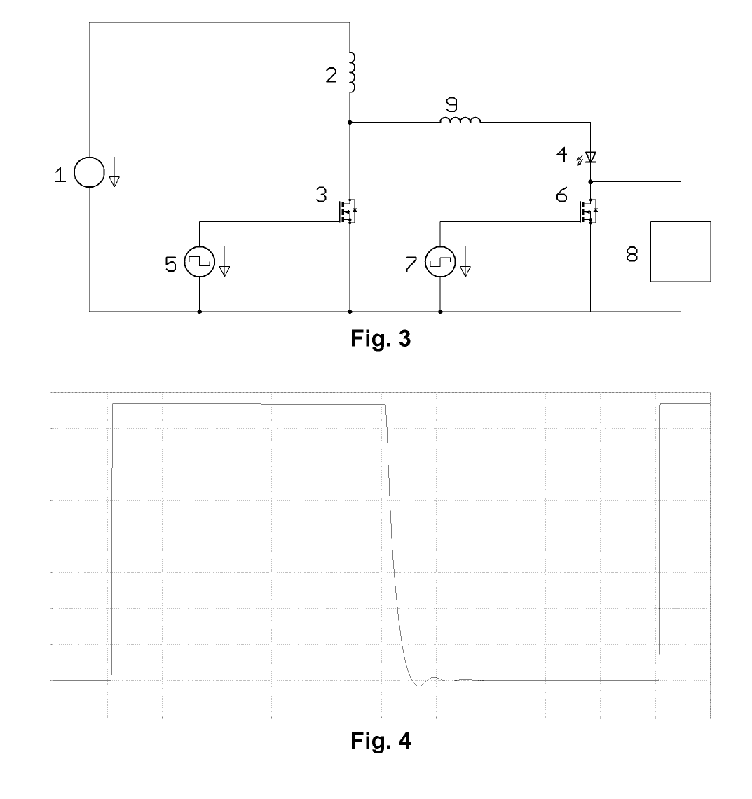

FIG. 3 shows a circuit in accordance with an embodiment of the present invention. Like the prior art circuit represented in FIG. 1, the circuit of FIG. 3 comprises a DC voltage source 1, an inductor 2 and a switch 3 driven by square wave source 5.

DC Voltage source 1 supplies a constant voltage to the driver circuit. The voltage is set to such a value that the required peak current flows through the light emitting device when it is modulated. Inductor 2 maintains a substantially constant current through the paralleled switch 3 and light emitting device 4.

Switch 3 is driven by square wave source 5. Square wave source 5 generates for instance a periodic square wave with a duty cycle substantially equal to 50%. Switch 3 is preferably fully switched on or off by square wave source 5. When switch 3 is open, the current maintained by inductor 2 flows through light emitting device 4. When switch 3 is turned on or closed, switch 3 tries to divert the same current away from the light emitting source 4 towards switch 3.

In order to reduce the influence of the series wiring inductance 9, the circuit of FIG. 3 further comprises an additional switch 6, an additional square wave source 7 and optionally a voltage limiting circuit 8. The additional switch 6 is connected in series with the light emitting device 4 between the output terminals of the power source such that the series connection of the additional switch 6 and the light emitting device 4 is connected in parallel to switch 3 between the output terminals of said power source. The square wave source 7 is driven out of phase to the square wave source 5. Square wave source 5 and 7 generate a periodic square wave with a duty cycle substantially equal to 50%. Whenever switch 3 is off, switch 6 is on and vice-versa.

When switch 3 is turned off, and series wiring inductance 9 tries to maintain the previous current through light emitting device 4, switch 6 turns off. The electrical path for the current now supplied by series wiring inductance 9 is then broken, and the current through light emitting device 4 stops abruptly. However, the voltage on the top node of switch 6 rises abruptly, driven by series wiring inductor 9. In order to prevent switch 6 to be destroyed by an overvoltage condition due to said rise in voltage, the voltage limiting circuit 8 limits said voltage to a high, but still safe level for switch 6. This voltage limiting again slows down the falling slope of the current through light emitting device 4, but the fall time is still substantially smaller than for the circuit in FIG. 1.

FIG. 4 shows the wave form of the current through light emitting device 4 for an example circuit according to FIG. 2. The X scale is 5 ns per division, Y scale is 2 A per division. The fall time in FIG. 3 is approximately 9.5 ns, and in FIG. 4 approximately 1.5 ns. Times are measured between 90% and 10% of amplitude.

The voltage limiting circuit can be one among the many known circuits employed for switched mode power circuits, for example an RC or RCD snubber, or a Z diode, or a diode biased to the required limiting voltage level.

1. A pulse modulated illumination source comprising
at least one light emitting device
a power source for generating a DC current to be supplied through said at least one light emitting device, said power source comprising a first and a second output terminal and said at least one light emitting device being connected between said first and second output terminals of said power source; and
a first controllable switching device and a first signal generator for generating a first electrical control signal for said first controllable switching device, said first controllable switching device being connected in parallel to said at least one light emitting device between said first and second output terminals of said power source; by and
a second controllable switching device and a second signal generator for generating a second electrical control signal for said second controllable switching device,
said second controllable switching device being connected in series with said at least one light emitting device between said first and second output terminals of said power source, the connection being such that said series connection of said second controllable switching device and said at least one light emitting device is connected in parallel to said first controllable switching device between said first and second output terminals of said power source, and
said second control signal being out of phase with said first control signal such that said second controllable switching device opens and decouples said light emitting device from said power source when said first controllable switching device closes.

2. The pulse modulated illumination source according to claim 1, further comprising a voltage limiting circuit, said voltage limiting circuit being connected so as to limit a peak voltage across said second controllable switching device when said second controllable switching device opens.

3. The pulse modulated illumination source according to claim 1, wherein said first and/or second control signals is/are square waves.

4. The pulse modulated illumination source according to claim 1, wherein said first control signal and said second control signal have the same frequency and wherein a phase difference between said first control signal and said second control signal is substantially 180°.

5. A-The pulse modulated illumination source according to claim 1, wherein said power source comprises a DC current source.

6. The pulse modulated illumination source according to claim 1, wherein said power source comprises a DC voltage source and an inductance coupled in series between the terminals of said power source.

7. The pulse modulated illumination source according to claim 1, wherein said at least one light emitting device comprises a laser diode or a laser diode array.
